(19) United States
(12) Patent Application Publication
(10) Pub. No.: US 2024/0030886 A1
(43) Pub. Date: Jan. 25, 2024

(54) ACOUSTIC WAVE DEVICE

(71) Applicant: Murata Manufacturing Co., Ltd., Nagaokakyo-shi (JP)

(72) Inventors: Kazunori INOUE, Nagaokakyo-shi (JP); Katsumi SUZUKI, Nagaokakyo-shi (JP); Tetsuya KIMURA, Nagaokakyo-shi (JP)

(21) Appl. No.: 18/374,697

(22) Filed: Sep. 29, 2023

Related U.S. Application Data
(63) Continuation of application No. PCT/JP2022/016892, filed on Mar. 31, 2022.
(60) Provisional application No. 63/168,306, filed on Mar. 31, 2021.

(51) Int. Cl. H03H 9/02; H03H 9/60; H03H 9/205; H03H 9/13

(52) U.S. Cl. CPC H03H 9/02157; H03H 9/605; H03H 9/205; H03H 9/132; H03H 9/02015

(57) ABSTRACT

An acoustic wave device includes a support, a piezoelectric layer, a first resonator including a first portion of the piezoelectric layer and a first functional electrode in the first portion of the piezoelectric layer, and a second resonator including a second portion of the piezoelectric layer and a second functional electrode in the second portion of the piezoelectric layer. A first hollow portion in the support overlaps the first resonator, and a second hollow portion in the support overlaps the second resonator. At least one first through-hole penetrates the piezoelectric layer and communicates with the first hollow portion, and at least one second through-hole penetrates the piezoelectric layer and communicates with the second hollow portion. A volume and a total opening area of the first hollow portion are larger than those of the second hollow portion.

### CROSS REFERENCE TO RELATED APPLICATIONS

This application claims the benefit of priority to Provisional Application No. 63/168,306 filed on Mar. 31, 2021 and is a Continuation Application of PCT Application No. PCT/JP2022/016892 filed on Mar. 31, 2022. The entire contents of each application are hereby incorporated herein by reference.

### BACKGROUND OF THE INVENTION

### 1. Field of the Invention

The present disclosure relates to an acoustic wave device including a piezoelectric layer.

### 2. Description of the Related Art

In the related art, an acoustic wave device using plate waves propagating through a piezoelectric layer made of LiNbO₃ is known. For example, Japanese Unexamined Patent Application Publication No. 2012-257019 discloses an acoustic wave device using Lamb waves as plate waves. In the disclosure, an IDT electrode is disposed on an upper surface of a piezoelectric layer (piezoelectric substrate) made of LiNbO₃ or LiTaO₃. A voltage is applied between a plurality of electrode fingers connected to one potential of the IDT electrode and a plurality of electrode fingers connected to the other potential. As a result, Lamb waves are excited. A reflector is disposed on each side of the IDT electrode. Accordingly, an acoustic wave resonator using plate waves is provided. A hollow portion is provided below the piezoelectric layer, and the piezoelectric layer has a through-hole that communicates with the hollow portion.

### SUMMARY OF THE INVENTION

In the acoustic wave device described in Japanese Unexamined Patent Application Publication No. 2012-257019, in a case where resonators having different sizes are disposed on the piezoelectric layer, if hollow portions or through-holes having the same size are formed for all of the resonators, the manufacturing efficiency of the acoustic wave device is likely to be reduced.

Preferred embodiments of the present invention provide acoustic wave devices that each can be manufactured with improved efficiency.

An acoustic wave device according to an aspect of a preferred embodiment of the present disclosure includes a support including a support substrate, a piezoelectric layer on or over the support, a first resonator including a first portion of the piezoelectric layer and a first functional electrode in the first portion of the piezoelectric layer, and a second resonator including a second portion of the piezoelectric layer and a second functional electrode in the second portion of the piezoelectric layer. The acoustic wave device includes a first hollow portion provided in the support and overlapping the first resonator as viewed in plan in a stacking direction of the support and the piezoelectric layer, and a second hollow portion provided in the support and overlapping the second resonator as viewed in plan in the stacking direction of the support and the piezoelectric layer. The acoustic wave device includes at least one first through-hole penetrating the piezoelectric layer and communicating with the first hollow portion, and at least one second through-hole penetrating the piezoelectric layer and communicating with the second hollow portion. A volume of the first hollow portion is larger than a volume of the second hollow portion, and a total opening area of the at least one first through-hole is larger than a total opening area of the at least one second through-hole.

According to preferred embodiments of the present invention, it is possible to provide acoustic wave devices that each can be manufactured with improved efficiency.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a schematic perspective view illustrating an external appearance of an acoustic wave device according to first and second aspects of a preferred embodiment of the present invention.

FIG. 1B is a plan view illustrating an electrode structure on a piezoelectric layer.

FIG. 2 is a sectional view of a portion taken along line A-A in FIG. 1A.

FIG. 3A is a schematic elevational cross-sectional view illustrating Lamb waves propagating through a piezoelectric film of an existing acoustic wave device.

FIG. 3B is a schematic elevational cross-sectional view illustrating waves of an acoustic wave device according to the present disclosure.

FIG. 4 is a schematic view illustrating bulk waves produced when a voltage is applied between a first electrode and a second electrode such that the second electrode is at a higher potential than the first electrode.

FIG. 5 is a diagram illustrating resonance characteristics of an acoustic wave device according to Preferred Embodiment 1 of the present invention.

FIG. 6 is a diagram illustrating the relationship between d/2p and a fractional bandwidth of a resonator of the acoustic wave device.

FIG. 7 is a plan view of another acoustic wave device according to Preferred Embodiment 1 of the present invention.

FIG. 8 is a reference diagram illustrating an example of resonance characteristics of the acoustic wave device.

FIG. 9 is a diagram illustrating the relationship between a fractional bandwidth and the amount of phase rotation of the impedance of spurious components, which is used as the magnitude of the spurious components and normalized by 180 degrees, when a large number of acoustic wave resonators are provided.

FIG. 10 is a diagram illustrating the relationship between d/2p, a metallization ratio MR, and the fractional bandwidth.

FIG. 11 is a diagram illustrating a map of the fractional bandwidth with respect to the Euler angles (0°, θ, ψ) of LiNbO₃ when d/p is set as close to zero as possible.

FIG. 12 is a partially cutaway perspective view illustrating an acoustic wave device according to Preferred Embodiment 1 of the present invention.

FIG. 13 is a plan view of an acoustic wave device according to a second preferred embodiment of the present invention.

FIG. 14 is a schematic sectional view of the acoustic wave device according to the second preferred embodiment of the present invention.

FIG. 15 is an explanatory diagram illustrating an example of a ladder filter using resonators.

FIG. 16 is a schematic sectional view of an acoustic wave device according to a modification of a preferred embodiment of the present invention.

FIG. 17 is a schematic sectional view of an acoustic wave device according to a modification of a preferred embodiment of the present invention.

FIG. 18 is a plan view of an acoustic wave device according to a modification of a preferred embodiment of the present invention.

FIG. 19 is a plan view of an acoustic wave device according to a modification of a preferred embodiment of the present invention.

FIG. 20 is a schematic sectional view of an acoustic wave device according to a modification of a preferred embodiment of the present invention.

FIG. 21 is a plan view of an acoustic wave device according to a modification of a preferred embodiment of the present invention.

FIG. 22 is a partial enlarged plan view of the acoustic wave device according to the modification of a preferred embodiment of the present invention shown in FIG. 21.

### DETAILED DESCRIPTION OF THE PREFERRED EMBODIMENTS

Acoustic wave devices according to first, second, and third aspects of a preferred embodiment of the present disclosure includes a piezoelectric layer made of lithium niobate or lithium tantalate, and a first electrode and a second electrode that face each other in a direction intersecting a thickness direction of the piezoelectric layer.

In the acoustic wave device according to the first aspect, bulk waves in a first-order thickness-shear mode are generated.

In the acoustic wave device according to the second aspect, the first electrode and the second electrode are adjacent electrodes, and d/p is set to be less than or equal to about 0.5, for example, where d is the thickness of the piezoelectric layer, and p is the center-to-center distance between the first electrode and the second electrode. With this configuration, in the first and second aspects, the Q factor can be increased even when size reduction is carried out.

In the acoustic wave device according to the third aspect, Lamb waves are used as plate waves. Thus, resonance characteristics based on the Lamb waves can be obtained.

An acoustic wave device according to a fourth aspect of a preferred embodiment of the present disclosure includes a piezoelectric layer made of lithium niobate or lithium tantalate, and an upper electrode and a lower electrode that face each other in a thickness direction of the piezoelectric layer with the piezoelectric layer interposed therebetween, and uses bulk waves.

Specific preferred embodiments of the acoustic wave devices according to the first to fourth aspects will be described hereinafter with reference to the drawings to clarify the present disclosure.

It is to be noted that the preferred embodiments described herein are illustrative and some of the elements in different preferred embodiments may be interchanged or combined with each other.

### Preferred Embodiment 1

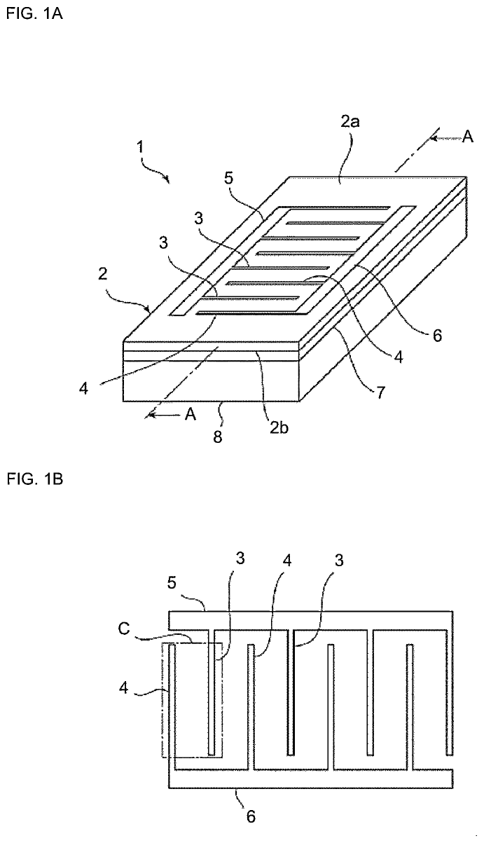

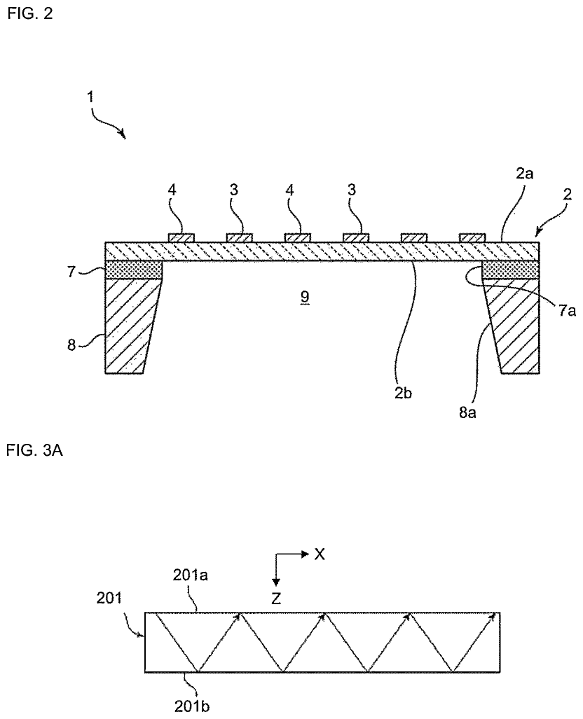

FIG. 1A is a schematic perspective view illustrating an external appearance of an acoustic wave device according to Preferred Embodiment 1 regarding the first and second aspects. FIG. 1B is a plan view illustrating an electrode structure on a piezoelectric layer. FIG. 2 is a sectional view of a portion taken along line A-A in FIG. 1A.

An acoustic wave device 1 includes a piezoelectric layer 2 made of lithium niobate (LiNbO₃). The piezoelectric layer 2 may be made of lithium tantalate (LiTaO₃). In the present preferred embodiment, the cut angles of LiNbO₃ or LiTaO₃ are set to Z-cut. However, rotated Y-cut or X-cut may be used. Preferably, a preferred propagation orientation is Y-propagation and X-propagation±about 30°, for example. The thickness of the piezoelectric layer 2 is not limited, but is preferably greater than or equal to about 50 nm and less than or equal to about 1000 nm to effectively excite the first-order thickness-shear mode, for example.

The piezoelectric layer 2 includes opposing first and second main surfaces 2a and 2b. An electrode 3 and an electrode 4 are disposed on the first main surface 2a. The electrode 3 is an example of a “first electrode”, and the electrode 4 is an example of a “second electrode”. In FIG. 1A and FIG. 1B, a plurality of electrodes 3 are a plurality of first electrode fingers connected to a first busbar 5. A plurality of electrodes 4 are a plurality of second electrode fingers connected to a second busbar 6. The plurality of electrodes 3 interdigitate with the plurality of electrodes 4.

The electrodes 3 and the electrodes 4 have a rectangular shape and have a length direction. Each of the electrode 3 and an adjacent one of the electrodes 4 face each other in a direction orthogonal to the length direction. The plurality of electrodes 3, the plurality of electrodes 4, the first busbar 5, and the second busbar 6 define an IDT (Interdigital Transducer) electrode. The length direction of the electrodes 3 and 4 and the direction orthogonal to the length direction of the electrodes 3 and 4 are both a direction intersecting the thickness direction of the piezoelectric layer 2. Thus, it can be said that each of the electrodes 3 and an adjacent one of the electrodes 4 face each other in the direction intersecting the thickness direction of the piezoelectric layer 2.

The length direction of the electrodes 3 and 4 and the direction orthogonal to the length direction of the electrodes 3 and 4 illustrated in FIG. 1A and FIG. 1B may be interchangeable. In other words, in FIG. 1A and FIG. 1B, the electrodes 3 and 4 may extend in a direction in which the first busbar 5 and the second busbar 6 extend. In this case, the first busbar 5 and the second busbar 6 extend in a direction in which the electrodes 3 and 4 extend in FIG. 1A and FIG. 1B.

A plurality of pairs of structures, each pair including one of the electrodes 3 connected to one potential and an adjacent one of the electrodes 4 connected to the other potential, are disposed in the direction orthogonal to the length direction of the electrodes 3 and 4. The expression “each of the electrodes 3 and an adjacent one of the electrodes 4” does not indicate that each of the electrodes 3 and a corresponding one of the electrodes 4 are arranged in direct contact with each other, but indicates that each of the electrodes 3 and a corresponding one of the electrodes 4 are arranged with a space therebetween.

In the case of each of the electrodes 3 and an adjacent one of the electrodes 4, an electrode to be connected to a hot electrode or a ground electrode, including the other electrodes 3 and 4, is not arranged between the adjacent electrodes 3 and 4. The number of pairs need not be an integer, but may be 1.5, 2.5, or the like. The center-to-center distance, that is, the pitch, between the electrodes 3 and 4 is preferably in a range greater than or equal to about 1 μm and less than or equal to about 10 μm, for example. The center-to-center distance between the electrodes 3 and 4 is a distance between the center of the width dimension of the electrode 3 in the direction orthogonal to the length direction of the electrode 3 and the center of the width dimension of the electrode 4 in the direction orthogonal to the length direction of the electrode 4. When at least one of the number of electrodes 3 and the number of electrodes 4 is more than one (when 1.5 or more pairs of electrodes, each pair of electrodes including one of the electrodes 3 and a corresponding one of the electrodes 4, are disposed), the center-to-center distance between the electrodes 3 and 4 indicates the average value of the center-to-center distances, each of which is between adjacent electrodes 3 and 4 in one of the 1.5 or more pairs. The width of each of the electrodes 3 and 4, that is, the dimension of each of the electrodes 3 and 4 in a direction in which the electrodes 3 and 4 face each other, are preferably in a range greater than or equal to about 150 nm and less than or equal to about 1000 nm, for example. The center-to-center distance between the electrodes 3 and 4 is a distance between the center of the dimension (width dimension) of the electrode 3 in the direction orthogonal to the length direction of the electrode 3 and the center of the dimension (width dimension) of the electrode 4 in the direction orthogonal to the length direction of the electrode 4.

In the present preferred embodiment, since a Z-cut piezoelectric layer is used, the direction orthogonal to the length direction of the electrodes 3 and 4 is a direction orthogonal to the polarization direction of the piezoelectric layer 2. This is not the case when a piezoelectric material having different cut angles is used as the piezoelectric layer 2. As used here, the term “orthogonal” is not limited to exactly orthogonal, but may mean substantially orthogonal (for example, an angle of about 90°±10° between the direction orthogonal to the length direction of the electrodes 3 and 4 and the polarization direction, for example).

A support 8 is stacked on the second main surface 2b of the piezoelectric layer 2 with an insulating layer 7 interposed therebetween. The insulating layer 7 and the support 8 have a frame-like shape. As illustrated in FIG. 2, the insulating layer 7 and the support 8 have cavities 7a and 8a, respectively. As a result, a hollow portion 9 is provided. The hollow portion 9 is provided not to interfere with the vibration of an excitation region C of the piezoelectric layer 2. Accordingly, the support 8 is stacked on the second main surface 2b, with the insulating layer 7 interposed therebetween, at a position at which the support 8 does not overlap a portion where at least one pair of electrodes 3 and 4 is disposed. The insulating layer 7 is optional. Thus, the support 8 can be stacked directly or indirectly on the second main surface 2b of the piezoelectric layer 2.

The insulating layer 7 is made of silicon oxide. Instead of silicon oxide, any other appropriate insulating material such as silicon oxynitride or alumina can be used. The support 8 is made of Si. The plane orientation on a surface of Si near the piezoelectric layer 2 may be (100) or (110) or may be (111). Preferably, high-resistance Si having a resistivity greater than or equal to about 4 kΩ is desirable. However, the support 8 can also be formed using an appropriate insulating material or semiconductor material. Examples of the material of the support 8 can include piezoelectrics such as aluminum oxide, lithium tantalate, lithium niobate, and quartz, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3, the plurality of electrodes 4, and the first and second busbars 5 and 6 are made of an appropriate metal or alloy such as Al or an AlCu alloy. In the present preferred embodiment, the electrodes 3 and 4 and the first and second busbars 5 and 6 have a structure in which an Al film is stacked on a Ti film. A contact layer other than a Ti film may be used.

During driving, an alternating-current voltage is applied between the plurality of electrodes 3 and the plurality of electrodes 4. More specifically, an alternating-current voltage is applied between the first busbar 5 and the second busbar 6. As a result, it is possible to provide resonance characteristics using bulk waves in a first-order thickness-shear mode excited in the piezoelectric layer 2.

The acoustic wave device 1 is designed such that d/p is less than or equal to about 0.5, for example, where d is the thickness of the piezoelectric layer 2 and p is the center-to-center distance between adjacent electrodes 3 and 4 in one of the plurality of pairs of electrodes 3 and 4. As a result, bulk waves in a first-order thickness-shear mode are effectively excited, which can provide good resonance characteristics. More preferably, d/p is less than or equal to about 0.24, for example. In this case, even better resonance characteristics can be provided.

As in the present preferred embodiment, when at least one of the number of electrodes 3 and the number of electrodes 4 is more than one, that is, when 1.5 or more pairs of electrodes 3 and 4, each pair including one of the electrodes 3 and a corresponding one of the electrodes 4, are disposed, the center-to-center distance p between adjacent electrodes 3 and 4 is the average distance of the center-to-center distances between the adjacent electrodes 3 and 4 in the respective pairs.

With the configuration described above, in the acoustic wave device 1 according to the present preferred embodiment, the Q factor is less likely to decrease even when the number of pairs of electrodes 3 and 4 is reduced to achieve size reduction. This is because the resulting resonator does not require a reflector on each side thereof and thus has a small propagation loss. The reflectors described above are not required because bulk waves in a first-order thickness-shear mode are used.

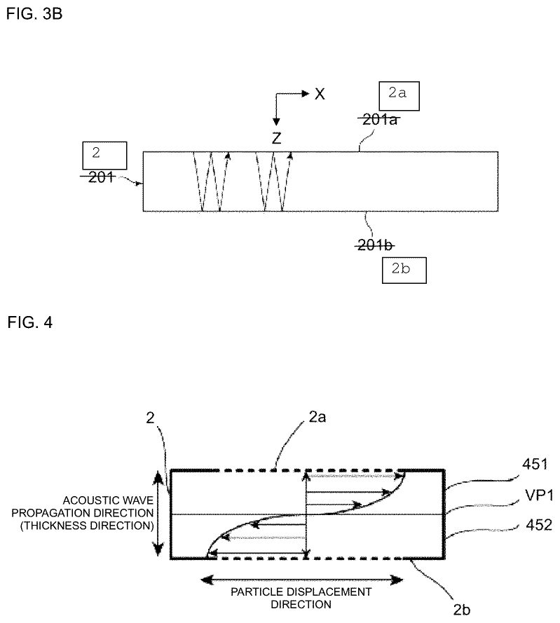

The difference between Lamb waves used in an existing acoustic wave device and bulk waves in a first-order thickness-shear mode will be described with reference to FIG. 3A and FIG. 3B.

FIG. 3A is a schematic elevational cross-sectional view illustrating Lamb waves propagating through a piezoelectric film of an existing acoustic wave device. The existing acoustic wave device is described in, for example, Japanese Unexamined Patent Application Publication No. 2012-257019. As illustrated in FIG. 3A, in the existing acoustic wave device, waves propagate through a piezoelectric film 201 in a manner as indicated by arrows. The piezoelectric film 201 includes a first main surface 201a and a second main surface 201b that face each other, and a thickness direction connecting the first main surface 201a and the second main surface 201b is the Z direction. The X direction refers to a direction in which electrode fingers of an IDT electrode are arranged. As illustrated in FIG. 3A, Lamb waves propagate in the X direction in the illustrated manner. The piezoelectric film 201 vibrates as a whole because the waves are plate waves. However, since the waves propagate in the X direction, a reflector is disposed on each side to provide resonance characteristics. This results in wave propagation loss. If size reduction is carried out, that is, if the number of pairs of electrode fingers is reduced, the Q factor decreases.

In the acoustic wave device 1 according to a preferred embodiment of the present embodiment, in contrast, as illustrated in FIG. 3B, vibration displacement occurs in a thickness-shear direction. Thus, the waves propagate substantially in a direction connecting the first main surface 2a and the second main surface 2b of the piezoelectric layer 2, that is, in the Z direction, to achieve resonance. That is, the waves have a significantly smaller X-direction component than a Z-direction component thereof. Since the wave propagation in the Z direction provides the resonance characteristics, no reflector is required. Accordingly, no propagation loss due to propagation through a reflector occurs. As a result, the Q factor is less likely to decrease even when the number of electrode pairs including the electrodes 3 and 4 is reduced to carry out size reduction.

As illustrated in FIG. 4, the amplitude directions of bulk waves in a first-order thickness-shear mode are opposite between a first region 451 included in the excitation region C of the piezoelectric layer 2 and a second region 452 included in the excitation region C. FIG. 4 schematically illustrates bulk waves produced when a voltage is applied between the electrode 3 and the electrode 4 such that the electrode 4 is at a higher potential than the electrode 3. The first region 451 is a region of the excitation region C located between a virtual plane VP1 and the first main surface 2a. The virtual plane VP1 is orthogonal to the thickness direction of the piezoelectric layer 2 and divides the piezoelectric layer 2 into two regions. The second region 452 is a region of the excitation region C located between the virtual plane VP1 and the second main surface 2b.

In the acoustic wave device 1, as described above, at least one pair of electrodes including an electrode 3 and an electrode 4 is disposed. Since the acoustic wave device 1 is not designed for wave propagation in the X direction, the acoustic wave device 1 does not necessarily need to include a plurality of electrode pairs including the electrodes 3 and 4. That is, the acoustic wave device 1 may simply include at least one pair of electrodes.

For example, the electrode 3 is an electrode connected to a hot potential, and the electrode 4 is an electrode connected to a ground potential. However, the electrode 3 may be connected to a ground potential, and the electrode 4 may be connected to a hot potential. In the present preferred embodiment, as described above, at least one pair of electrodes includes an electrode connected to a hot potential or an electrode connected to a ground potential, and does not include a floating electrode.

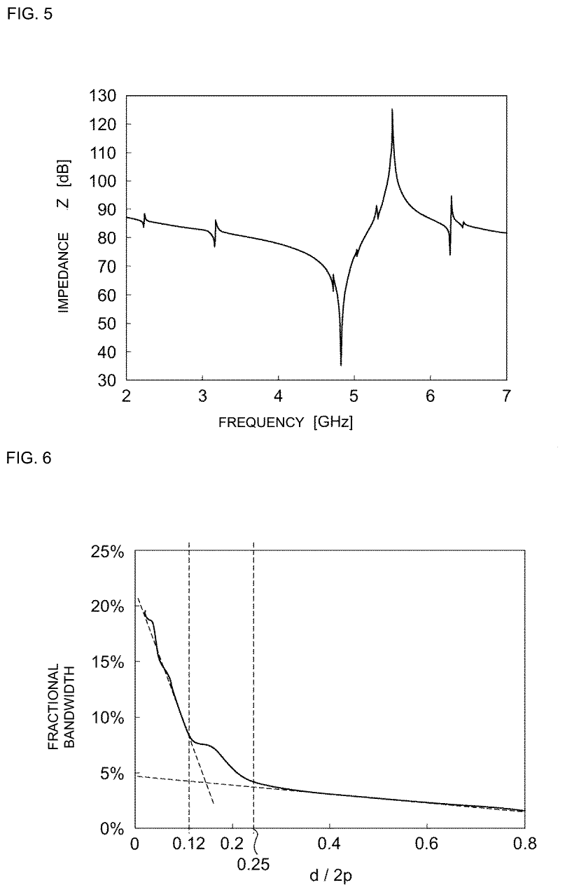

FIG. 5 illustrates resonance characteristics of the acoustic wave device according to Preferred Embodiment 1 of the present disclosure. An example of the acoustic wave device 1 with the resonance characteristics has design parameters as follows.

Piezoelectric layer 2: LiNbO₃ having Euler angles (0°, 0°, 90°, with a thickness of about 400 nm. The length of a region where the electrode 3 and the electrode 4 overlap when viewed in the direction orthogonal to the length direction of the electrode 3 and the electrode 4, that is, the excitation region C, is about 40 μm, the number of pairs of electrodes, each including the electrodes 3 and 4, is 21, the center-to-center distance between electrodes is about 3 μm, and the width of the electrodes 3 and 4 is about 500 nm, and d/p is about 0.133.

Insulating layer 7: silicon oxide film having a thickness of about 1 μm.

Support 8: Si.

The length of the excitation region C is a dimension of the excitation region C in the length direction of the electrodes 3 and 4.

In the present preferred embodiment, all the distances between electrodes in a plurality of electrode pairs including the electrodes 3 and 4 are set to be equal. That is, the electrodes 3 and the electrodes 4 are disposed at equal pitches.

As is clear from FIG. 5, good resonance characteristics with a fractional bandwidth of about 12.5%, for example, are obtained, even though no reflector is disposed.

In the present preferred embodiment, when the thickness of the piezoelectric layer 2 is represented by d and the center-to-center distance between electrodes including the electrode 3 and the electrode 4 is represented by p, as described above, d/p is less than or equal to about 0.5, and more preferably less than or equal to about 0.24, for example. This will be described with reference to FIG. 6.

A plurality of acoustic wave devices are obtained in a manner similar to that of the acoustic wave device having the resonance characteristics illustrated in FIG. 5, except that d/2p is changed. FIG. 6 is a diagram illustrating the relationship between d/2p and the fractional bandwidth of a resonator of the acoustic wave device.

As is clear from FIG. 6, when d/2p exceeds about 0.25, that is, d/p>about 0.5, the fractional bandwidth remains less than about 5% even if d/p is adjusted, for example. When d/2p about 0.25, that is, d/p about 0.5, in contrast, changing d/p within this range makes it possible to provide a fractional bandwidth of greater than or equal to about 5%, for example. That is, a resonator having a high coupling coefficient can be provided. When d/2p is less than or equal to about 0.12, that is, when d/p is less than or equal to about 0.24, the fractional bandwidth can be increased to be greater than or equal to about 7%, for example. In addition, adjusting d/p within this range makes it possible to provide a resonator having a wider fractional bandwidth. Thus, a resonator having an even higher coupling coefficient can be realized. It can therefore be appreciated that, as in the acoustic wave device according to the second aspect of the present disclosure, setting d/p to be less than or equal to about 0.5, for example, makes it possible to provide a resonator having a high coupling coefficient that uses bulk waves in a first-order thickness-shear mode.

As described above, at least one pair of electrodes may be one pair. When one pair of electrodes is used, p is the center-to-center distance of the adjacent electrodes 3 and 4. When 1.5 or more pairs of electrodes are used, the average distance of the center-to-center distances of adjacent electrodes 3 and 4 is desirably represented by p.

Further, when the piezoelectric layer 2 has variations in thickness, a value of the averaged thickness may be used as the thickness d of the piezoelectric layer.

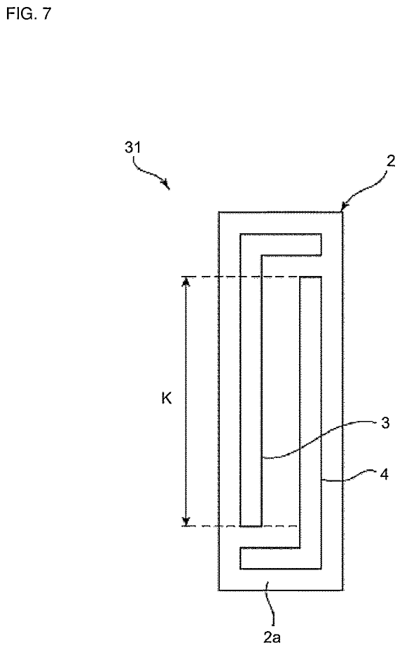

FIG. 7 is a plan view of another acoustic wave device according to Preferred Embodiment 1 of the present disclosure. In an acoustic wave device 31, a pair of electrodes 3 and 4 is disposed on the first main surface 2a of the piezoelectric layer 2. In FIG. 7, K represents an intersecting width. As described above, the acoustic wave device 31 according to the present disclosure may include one pair of electrodes. Also in this case, setting d/p, described above, to be less than or equal to about 0.5, for example, makes it possible to effectively excite bulk waves in a first-order thickness-shear mode.

In the acoustic wave device 1, an excitation region is a region in which any adjacent electrodes 3 and 4 among the plurality of electrodes 3 and the plurality of electrodes 4 overlap each other when viewed in a direction in which the adjacent electrodes 3 and 4 face each other, and, preferably, a metallization ratio MR of the adjacent electrodes 3 and 4 with respect to the excitation region desirably satisfies MR≤about 1.75 (d/p)+0.075, for example. That is, a region in which adjacent electrodes 3 and 4 overlap each other when viewed in a direction in which the electrode 3 and the electrode 4 are arranged is an excitation region, and MR≤about 1.75 (d/p)+0.075, for example, is preferably satisfied, where MR is the metallization ratio of the pluralities of electrode 3 and 4 with respect to the excitation region. In this case, spurious components can be effectively reduced in magnitude.

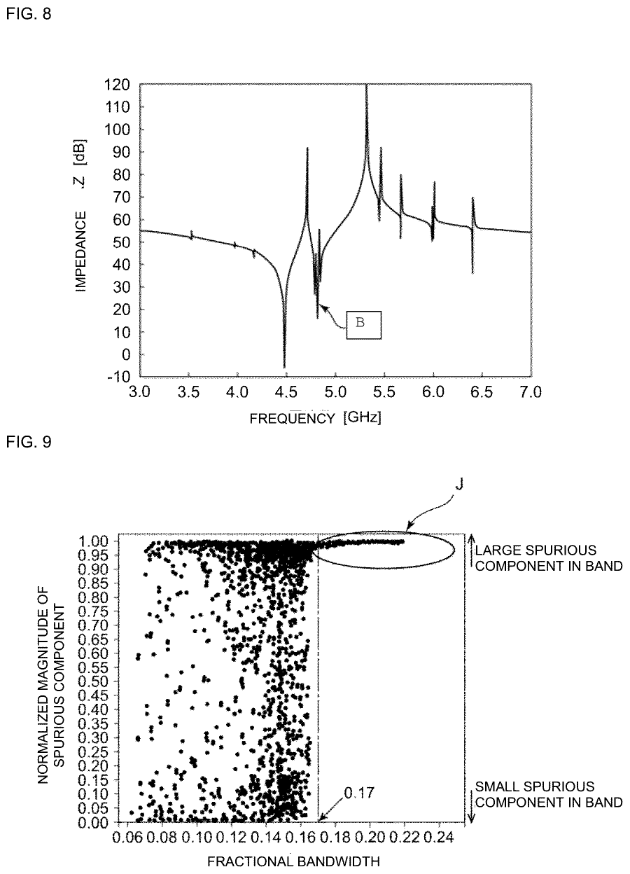

This will be described with reference to FIG. 8 and FIG. 9. FIG. 8 is a reference diagram illustrating an example of the resonance characteristics of the acoustic wave device 1 described above. Spurious components indicated by arrow B appear between the resonant frequency and the anti-resonant frequency. It is assumed that d/p is about 0.08 and the Euler angles of LiNbO₃ are (0°, 0°, 90°), for example. It is also assumed that the metallization ratio MR described above is about 0.35, for example.

The metallization ratio MR will be described with reference to FIG. 1B. In the electrode structure illustrated in FIG. 1B, a focus is placed on a pair of electrodes 3 and 4. In this case, it is assumed that only this pair of electrodes 3 and 4 is disposed. In this case, a portion surrounded by an alternate long and short dash line C is an excitation region. The excitation region is a region of the electrode 3 that overlaps the electrode 4, a region of the electrode 4 that overlaps the electrode 3, and a region where the electrode 3 and the electrode 4 overlap each other within a region between the electrode 3 and the electrode 4 when the electrode 3 and the electrode 4 are viewed in the direction orthogonal to the length direction of the electrodes 3 and 4, that is, in an opposing direction. The area of the electrodes 3 and 4 in the excitation region C with respect to the area of the excitation region is the metallization ratio MR. That is, the metallization ratio MR is the ratio of the area of the metallization portion to the area of the excitation region.

When a plurality of pairs of electrodes are disposed, the ratio of the metallization portions included in all of the excitation regions to the sum of the areas of the excitation regions is desirably represented by MR.

FIG. 9 is a diagram illustrating the relationship between a fractional bandwidth and the amount of phase rotation of the impedance of spurious components, which is used as the magnitude of the spurious components and normalized by 180 degrees, when a large number of acoustic wave resonators are provided according to the present preferred embodiment. The fractional bandwidth is adjusted by variously changing the film thickness of the piezoelectric layer and the dimensions of the electrodes. FIG. 9 illustrates results obtained when a piezoelectric layer made of Z-cut LiNbO₃ is used. Also in a case where a piezoelectric layer having other cut angles is used, a similar tendency is obtained.

In a region surrounded by an ellipse J in FIG. 9, the magnitude of spurious components is as large as about 1.0, for example. As is clear from FIG. 9, when the fractional bandwidth exceeds about 0.17, for example, that is, when the fractional bandwidth exceeds about 17%, large spurious components with a spurious level of greater than or equal to 1 appear in the pass band even when the parameters for forming the fractional bandwidth are changed. That is, as in the resonance characteristics illustrated in FIG. 8, large spurious components indicated by arrow B appear in the band. Therefore, the fractional bandwidth is preferably less than or equal to about 17%, for example. In this case, spurious components can be reduced by adjusting, for example, the film thickness of the piezoelectric layer 2 and the dimensions of the electrodes 3 and 4.

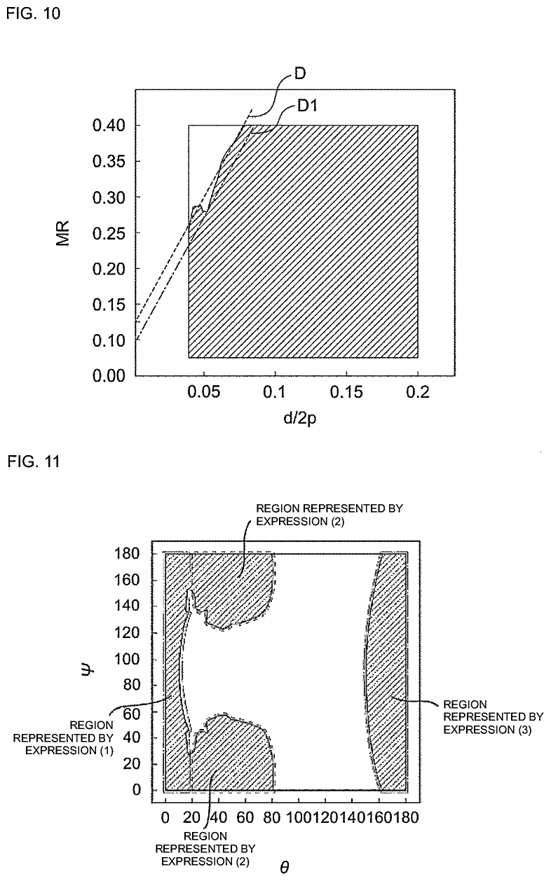

FIG. 10 is a diagram illustrating the relationship between d/2p, the metallization ratio MR, and the fractional bandwidth. In the acoustic wave device described above, the values of d/2p and MR are made different to provide various acoustic wave devices, and the fractional bandwidths are measured. In FIG. 10, a hatched portion to the right of a broken line D represents a region having a fractional bandwidth of less than or equal to about 17%, for example. The boundary between the hatched region and a non-hatched region is represented by MR=about 3.5(d/2p)+0.075, for example. That is, MR=about 1.75(d/p)+0.075, for example. Accordingly, preferably, MR about 1.75 (d/p)+0.075, for example. In this case, a fractional bandwidth of less than or equal to about 17%, for example, is likely to be obtained. A more preferable example of the region described above is a region to the right of an alternate long and short dash line D1 in FIG. 10, which represents MR=about 3.5 (d/2p)+0.05, for example. That is, setting MR≤about 1.75 (d/p)+0.05 ensures that a fractional bandwidth of less than or equal to about 17% can be obtained, for example.

FIG. 11 is a diagram illustrating a map of the fractional bandwidth with respect to the Euler angles (0°, θ, ψ) of LiNbO₃ when d/p is set as close to zero as possible. In FIG. 11, hatched portions represent regions where a fractional bandwidth of at least greater than or equal to about 5% is obtained, for example. The ranges of the regions are approximated to provide ranges represented by Expression (1), Expression (2), and Expression (3) below.

(0°±10°,0° to 20°,any ψ) Expression (1)

(0°±10°,20° to 80°, 0° to 60° (1−(θ−50)²/900)_{1/2}) or (0°±10°, 20° to 80°, [180°−60° (1−(θ−50)²/900)_{1/2}] to 180°) Expression (2)

(0°±10°,[180°−30° (1−(ψ−90)²/8100)_{1/2}] to 180°,any ψ) Expression (3)

Accordingly, the Euler angle range represented by Expression (1), Expression (2), or Expression (3) above is preferable since a sufficient large fractional bandwidth can be obtained.

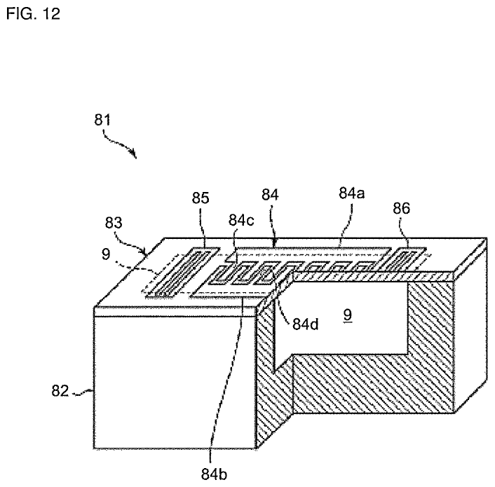

FIG. 12 is a partially cutaway perspective view illustrating the acoustic wave device according to Preferred Embodiment 1 of the present disclosure. An acoustic wave device 81 includes a support substrate 82. The support substrate 82 includes an open recess in an upper surface thereof. A piezoelectric layer 83 is stacked on the support substrate 82. As a result, a hollow portion 9 is provided. An IDT electrode 84 is disposed on the piezoelectric layer 83 above the hollow portion 9. Reflectors 85 and 86 are disposed on both sides of the IDT electrode 84 in the acoustic wave propagation direction. In FIG. 12, the outer perimeter of the hollow portion 9 is indicated by a broken line. The IDT electrode 84 includes first and second busbars 84a and 84b, a plurality of electrodes 84c serving as first electrode fingers, and a plurality of electrodes 84d serving as second electrode fingers. The plurality of electrodes 84c are connected to the first busbar 84a. The plurality of electrodes 84d are connected to the second busbar 84b. The plurality of electrodes 84c interdigitate with the plurality of electrodes 84d.

In the acoustic wave device 81, an alternating-current electric field is applied to the IDT electrode 84 above the hollow portion 9. As a result, Lamb waves serving as plate waves are excited. Since the reflectors 85 and 86 are disposed on both sides, the resonance characteristics based on the Lamb waves described above can be obtained.

As described above, the acoustic wave device according to the present disclosure may use plate waves.

### Preferred Embodiment 2

An acoustic wave device according to Preferred Embodiment 2 of the present invention will be described hereinafter. In the description of Preferred Embodiment 2, elements having configurations, operations, and functions similar to those in Preferred Embodiment 1 will not be described to avoid redundant description, and differences will be mainly described hereinafter.

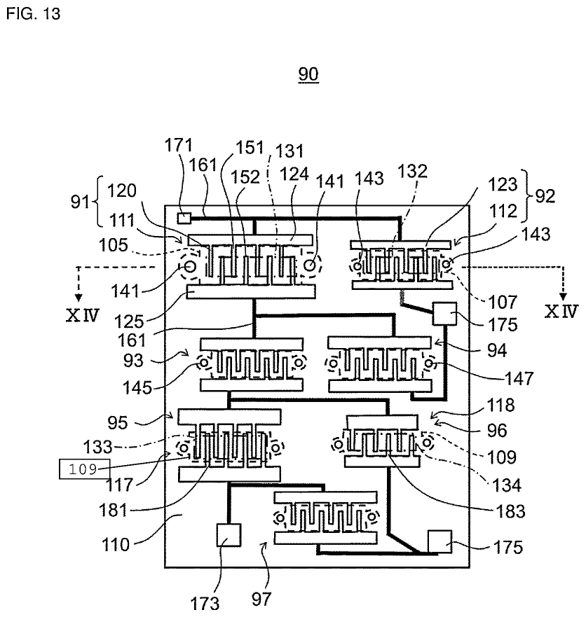

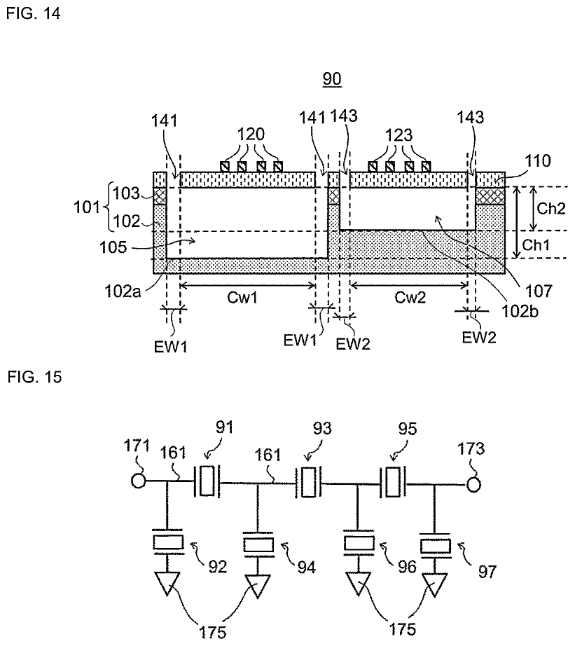

Reference is made to FIG. 13 and FIG. 14. FIG. 13 is a plan view of an acoustic wave device 90 according to Preferred Embodiment 2 of the present disclosure. FIG. 14 is a schematic sectional view of the acoustic wave device 90 according to Preferred Embodiment 2 of the present disclosure, taken along line XIV-XIV in FIG. 13. The term “in plan” means as viewed in the thickness direction of the acoustic wave device 90, that is, as viewed in the stacking direction of a support 101 and a piezoelectric layer 110.

As illustrated in FIG. 13, the acoustic wave device 90 includes, for example, a first resonator 91 to a seventh resonator 97. The first resonator 91 to the seventh resonator 97 have different sizes. Among the seven resonators, the first resonator 91 and the second resonator 92 will be described in detail with reference to FIG. 14. The acoustic wave device 90 further includes the support 101, the piezoelectric layer 110, a first hollow portion 105, a second hollow portion 107, a first through-hole 141, and a second through-hole 143.

The support 101 includes a support substrate 102 and an intermediate layer 103. For example, the support 101 includes a multilayer body including the support substrate 102 made of Si and the intermediate layer 103 stacked on the support substrate 102 and made of SiOx. The side of the support substrate 102 near the piezoelectric layer 110 is recessed to define a first recess 102a and a second recess 102b.

The piezoelectric layer 110 is disposed on the intermediate layer 103 and is made of lithium niobate or lithium tantalate.

The support 101 includes, in the support substrate 102 and the intermediate layer 103, the first hollow portion 105 and the second hollow portion 107 that open toward the piezoelectric layer 110. The first hollow portion 105 and the second hollow portion 107 are spaces defined by the support 101 and the piezoelectric layer 110. A portion of the first hollow portion 105 is defined by the first recess 102a in the support substrate 102, and a portion of the second hollow portion 107 is defined by the second recess 102b in the support substrate 102.

The first resonator 91 includes a first portion 111, which is a portion of the piezoelectric layer 110 illustrated in FIG. 13, and a first functional electrode 120 disposed in the first portion 111. Likewise, the second resonator 92 includes a second portion 112, which is a portion of the piezoelectric layer 110, and a second functional electrode 123 disposed in the second portion 112. The fifth resonator 95 includes a third portion 117, which is a portion of the piezoelectric layer 110, and a third functional electrode 181 disposed in the third portion 117. The sixth resonator 96 includes a fourth portion 118, which is a portion of the piezoelectric layer 110, and a fourth functional electrode 183 disposed in the fourth portion 118.

The first functional electrode 120 includes a first busbar 124 and a second busbar 125, which face each other, a plurality of first electrode fingers 151 connected to the first busbar 124, and a plurality of second electrode fingers 152 connected to the second busbar 125.

Each of the first electrode fingers 151 includes a proximal end connected to the first busbar 124, and each of the second electrode fingers 152 includes a proximal end connected to the second busbar 125. The first busbar 124 and the second busbar 125 are connected to wiring electrodes 161. The first electrode fingers 151 interdigitate with the second electrode fingers 152, and each of the first electrode fingers 151 and an adjacent one of the second electrode fingers 152 define a pair of electrodes. The second functional electrode 123 also has a similar configuration.

The first hollow portion 105 overlaps the first resonator 91 as viewed in plan in the stacking direction of the support 101 and the piezoelectric layer 110. The second hollow portion 107 overlaps the second resonator 92 as viewed in plan in the stacking direction of the support 101 and the piezoelectric layer 110.

The first through-hole 141 penetrates the piezoelectric layer 110 and communicates with the first hollow portion 105. The second through-hole 143 penetrates the piezoelectric layer 110 and communicates with the second hollow portion 107. At least one first through-hole 141 is disposed in the first portion 111, and at least one second through-hole 143 is disposed in the second portion 112.

In the present preferred embodiment, the piezoelectric layer 110 includes a plurality of first through-holes 141 penetrating the piezoelectric layer 110 in such a manner that the first functional electrode 120 is interposed between the first through-holes 141. The plurality of first through-holes 141 extend to reach the first hollow portion 105. The piezoelectric layer 110 also includes a plurality of second through-holes 143 penetrating the piezoelectric layer 110 in such a manner that the second functional electrode 123 is interposed between the second through-holes 143. The plurality of second through-holes 143 extend to reach the second hollow portion 107.

The first resonator 91 is relatively larger than the second resonator 92, and the second resonator 92 is relatively smaller than the first resonator 91. As used here, the size of the resonators is the area of an intersection region in which the plurality of first electrode fingers 151 and the plurality of second electrode fingers 152 included in each resonator overlap each other when viewed in a direction in which the electrode fingers are arranged, in other words, the area of a region in which the sets of electrode fingers are alternately arranged so as to respectively extend from busbars in one pair included in the resonator.

In FIG. 13, the area of a first region 131, which is the intersection region of the first resonator 91, is larger than the area of a second region 132, which is the intersection region of the second resonator 92. It can thus be said that the size of the first resonator 91 is relatively larger than the size of the second resonator 92. Further, the area of a third region 133, which is the intersection region of the fifth resonator 95, is larger than the area of a fourth region 134, which is the intersection region of the sixth resonator 96. Thus, the size of the fifth resonator 95 is relatively larger than the size of the sixth resonator 96.

The volume of the first hollow portion 105, which is provided for the first resonator 91 having a relatively large size among the first resonator 91 and the second resonator 92, is larger than the volume of the second hollow portion 107, which is provided for the second resonator 92 having a relatively small size among the first resonator 91 and the second resonator 92. Specifically, the area of the first hollow portion 105 as viewed in plan in the stacking direction of the support substrate 102 and the piezoelectric layer 110 is larger than the area of the second hollow portion 107 as viewed in plan in the stacking direction. For example, as illustrated in FIG. 14, a length Cw1 of the first hollow portion 105 in its longitudinal direction is larger than a length Cw2 of the second hollow portion 107 in its longitudinal direction. Accordingly, as viewed in plan, the area of the first resonator 91 is larger than the area of the second resonator 92.

In the stacking direction of the support substrate 102 and the piezoelectric layer 110, furthermore, a depth Ch1 of the first hollow portion 105 is larger than a depth Ch2 of the second hollow portion 107. As a result, a relatively large hollow portion is provided for a relatively large resonator. This ensures that an excitation space is easily secured.

The volume of a third hollow portion 108 provided for the fifth resonator 95, which is relatively large among the fifth resonator 95 and the sixth resonator 96, is smaller than the volume of a fourth hollow portion 109 provided for the sixth resonator 96, which is relatively small among the fifth resonator 95 and the sixth resonator 96.

Preferred Embodiment 2 presents a case where both the depth of the first hollow portion 105 and the area of the first hollow portion 105 as viewed in plan are larger than those of the second hollow portion 107. However, only one of the depth and the area as viewed in plan may be larger. As a result, a hollow portion smaller than that in Preferred Embodiment 2 is provided for a resonator having a relatively large intersection region and thus having poor heat dissipation properties, thereby improving the heat dissipation properties.

The total opening area of at least the first through-holes 141 reaching the first hollow portion 105 is larger than the total opening area of the second through-holes 143 reaching the second hollow portion 107. For example, the plurality of first through-holes 141 may have a larger opening area than the plurality of second through-holes 143. Alternatively, the opening area of each of the first through-holes 141 may be larger than the opening area of each of the second through-holes 143 as viewed in plan. For example, a diameter EW1 of the first through-holes 141 is larger than a diameter EW2 of the second through-holes 143. The opening area of the plurality of third through-holes 145 reaching the third hollow portion 108 is larger than the opening area of the plurality of fourth through-holes 147 reaching the fourth hollow portion 109. As described above, a through-hole having a relatively large opening area is provided for a hollow portion having a relatively large volume. This may allow an etching liquid to smoothly enter the hollow portion to be formed and can improve the manufacturing efficiency. In addition, a relatively small through-hole is provided for a relatively small hollow portion. This can implement space saving on the piezoelectric layer. Therefore, both improvement in manufacturing efficiency and space saving can be achieved.

As illustrated in FIG. 15, a plurality of resonators including the first resonator 91 to the seventh resonator 97 define, for example, a ladder filter including series arm resonators disposed in a path connecting an input terminal 171 and an output terminal 173 and parallel arm resonators disposed between the path and ground 175. The first resonator 91, the third resonator 93, and the fifth resonator 95 are series arm resonators, and the second resonator 92, the fourth resonator 94, the sixth resonator 96, and the seventh resonator 97 are parallel arm resonators. Although not illustrated, the first resonator 91 and the fifth resonator 95 may be resonators for transmission or reception, and the second resonator 92 and the sixth resonator 96 may be resonators for reception or transmission.

While Preferred Embodiment 2 presents a case where all of the first resonator 91 to the seventh resonator 97 are disposed on the same piezoelectric layer 110, at least one resonator among the first resonator 91 to the seventh resonator 97 may be disposed on a different piezoelectric layer from the other resonators.

As described above, the acoustic wave device 90 according to Preferred Embodiment 2 includes the support 101 including the support substrate 102, the piezoelectric layer 110 disposed on the support 101, the first resonator 91 including the first portion 111 of the piezoelectric layer 110 and the first functional electrode 120 disposed in the first portion 111 of the piezoelectric layer 110, and the second resonator 92 including the second portion 112 of the piezoelectric layer 110 and the second functional electrode 123 disposed in the second portion 112 of the piezoelectric layer 110. The acoustic wave device 90 includes the first hollow portion 105 provided in the support 101 and overlapping the first resonator 91 as viewed in plan in a stacking direction of the support 101 and the piezoelectric layer 110, and the second hollow portion 107 provided in the support 101 and overlapping the second resonator 92 as viewed in plan in the stacking direction of the support 101 and the piezoelectric layer 110. The acoustic wave device 90 includes at least one first through-hole 141 penetrating the piezoelectric layer 110 and communicating with the first hollow portion 105, and at least one second through-hole 143 penetrating the piezoelectric layer 110 and communicating with the second hollow portion 107. The volume of the first hollow portion 105 is larger than the volume of the second hollow portion 107, and the opening area of the at least one first through-hole 141 is larger than the opening area of the at least one second through-hole 143.

As described above, since the opening area of the first through-hole 141 communicating with the first hollow portion 105 having a larger volume than the second hollow portion 107 is larger than the opening area of the second through-hole 143 communicating with the second hollow portion 107, the first resonator 91 can be manufactured with improved efficiency although the size of the hollow portion is large.

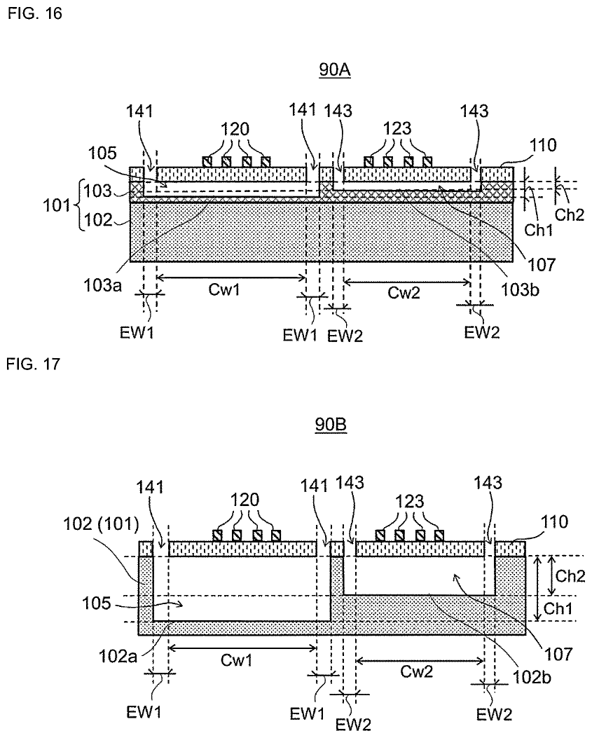

Next, Modification 1 of Preferred Embodiment 2 will be described with reference to FIG. 16. FIG. 16 is a schematic sectional view of an acoustic wave device 90A according to Modification 1 of Preferred Embodiment 2. The acoustic wave device 90A has a configuration in which a hollow portion is provided only in an intermediate layer. The intermediate layer 103 includes a first recess 103a and a second recess 103b. The first recess 103a defines a first hollow portion 105, and the second recess 103b defines a second hollow portion 107.

Next, Modification 2 of Preferred Embodiment 2 will be described with reference to FIG. 17. FIG. 17 is a schematic sectional view of an acoustic wave device 90B according to Modification 2 of Preferred Embodiment 2. In the acoustic wave device 90B, the support 101 includes only the support substrate 102 and does not include the intermediate layer 103. In this case, a hollow portion is provided only in the support substrate. Accordingly, a first recess 102a in the support substrate 102 defines the first hollow portion 105 and a second recess 102b in the support substrate 102 defines the second hollow portion 107.

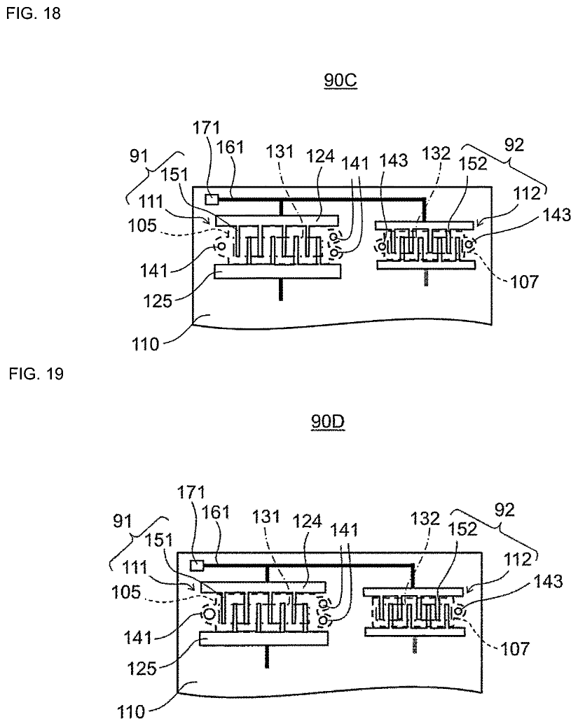

Next, Modification 3 of Preferred Embodiment 2 will be described with reference to FIG. 18. FIG. 18 is a plan view of an acoustic wave device 90C according to Modification 3 of Preferred Embodiment 2. As illustrated in FIG. 18, a case where the opening area of the plurality of first through-holes 141 is larger than the opening area of the plurality of second through-holes 143 includes a case where the opening area of each of the first through-holes 141 is the same as the opening area of each of the second through-holes 143 and the total number of first through-holes 141 is larger than the total number of second through-holes 143. In the acoustic wave device 90C, for example, the diameter EW1 of the first through-holes 141 and the diameter EW2 of the second through-holes 143 have the same length, whereas the total number of first through-holes 141 is three and the total number of second through-holes 143 is two.

Next, Modification 4 of Preferred Embodiment 2 will be described with reference to FIG. 19. FIG. 19 is a plan view of an acoustic wave device 90D according to Modification 4 of Preferred Embodiment 2. As illustrated in FIG. 19, through-holes may be provided on both sides of a hollow portion having a relatively large volume. First through-holes 141 are provided on both sides of the first hollow portion 105 in its longitudinal direction. A through-hole may be provided only on one side of a hollow portion having a relatively small volume. For example, only one second through-hole 143 communicating with the second hollow portion 107 is provided.

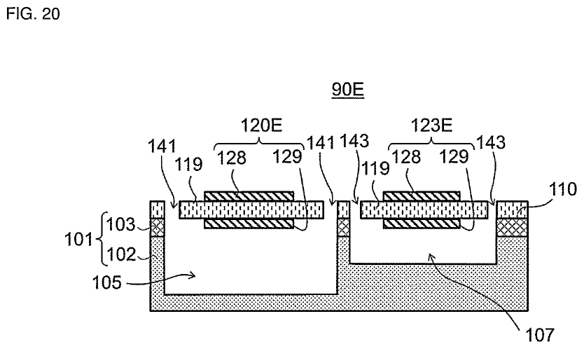

Next, Modification 5 of Preferred Embodiment 2 will be described with reference to FIG. 20. FIG. 20 is a schematic sectional view of an acoustic wave device 90E according to Modification 5 of Preferred Embodiment 2. As illustrated in FIG. 20, in the acoustic wave device 90E, first and second functional electrodes 120E and 123E may be BAW (Bulk Acoustic Wave) elements. Each of the first and second functional electrodes 120E and 123E includes an upper electrode 128 and a lower electrode 129 that face each other in the thickness direction of the piezoelectric layer 110 with the piezoelectric layer 110 interposed therebetween.

The upper electrodes 128 and the lower electrodes 129 are disposed on membrane portions 119. The upper electrodes 128 are disposed on an exposed surface of the membrane portions 119. The lower electrodes 129 are disposed on the side of the membrane portions 119 adjacent to the first hollow portion 105 and the second hollow portion 107. Through-holes 141 and 143 can make it less likely that the piezoelectric layer 119 will be damaged due to differences in air pressure.

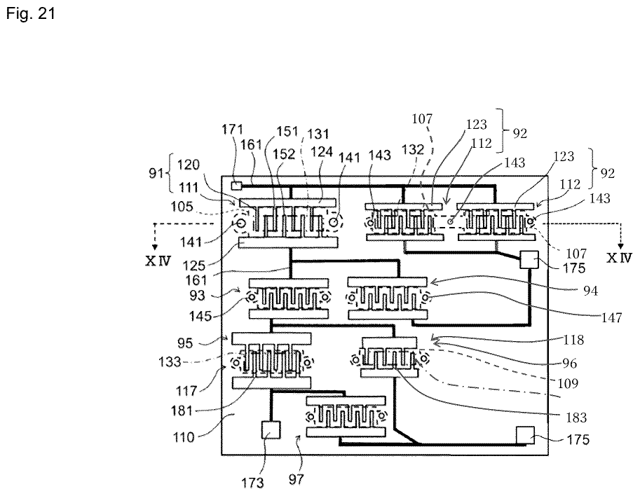

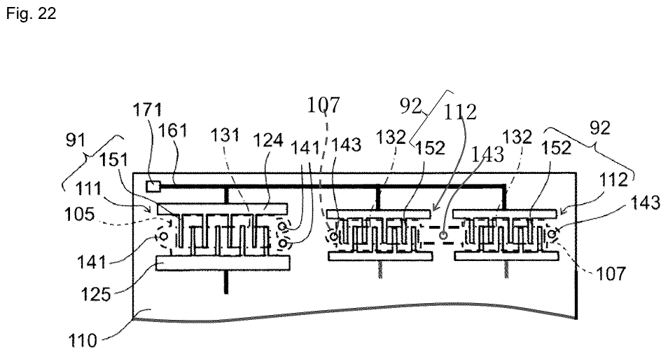

A modification of a preferred embodiment of the present invention is described with reference to FIGS. 21 and 22. In the present preferred embodiment a second through-hole 143 communicates with each of two second hollow portions 107 via a connection passage.

The present invention is not limited to the preferred embodiments described above and may be modified as follows.

In Preferred Embodiment 2 described above, the first functional electrode 120 and the second functional electrode 123 are disposed on the exposed surface of the piezoelectric layer 110. However, it is not limited thereto. The first functional electrode 120 and the second functional electrode 123 may be disposed on the side of the piezoelectric layer 110 adjacent to the first hollow portion 105 and the second hollow portion 107, respectively.

While preferred embodiments of the present invention have been described with a certain degree of particularity, it is understood that the disclosure of these preferred embodiments may be changed in the details of construction and that changes in the combination and order of elements in the preferred embodiments can be made without departing from the spirit and scope of the present invention as claimed.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on or over the support;
a first resonator including a first portion of the piezoelectric layer and a first functional electrode in the first portion of the piezoelectric layer;
a second resonator including a second portion of the piezoelectric layer and a second functional electrode in the second portion of the piezoelectric layer;
a first hollow portion provided in the support and overlapping the first resonator as viewed in plan in a stacking direction of the support and the piezoelectric layer;
a second hollow portion provided in the support and overlapping the second resonator as viewed in plan in the stacking direction of the support and the piezoelectric layer;
at least one first through-hole penetrating the piezoelectric layer and communicating with the first hollow portion; and
at least one second through-hole penetrating the piezoelectric layer and communicating with the second hollow portion; wherein
a volume of the first hollow portion is larger than a volume of the second hollow portion; and
a total opening area of the at least one first through-hole is larger than a total opening area of the at least one second through-hole.

2. The acoustic wave device according to claim 1, wherein an opening area of each of the at least one first through-hole is larger than an opening area of each of the at least one second through-hole as viewed in plan.

3. The acoustic wave device according to claim 1, wherein a number of first through-holes included in the at least one first through-hole is larger than a number of second through-holes included in the at least one second through-hole.

4. The acoustic wave device according to claim 1, wherein as viewed in plan, an area of the first resonator is larger than an area of the second resonator.

5. The acoustic wave device according to claim 1, wherein an area of the first hollow portion as viewed in plan is larger than an area of the second hollow portion as viewed in plan.

6. The acoustic wave device according to claim 5, wherein a depth of the first hollow portion is larger than a depth of the second hollow portion.

7. The acoustic wave device according to claim 1, wherein the at least one first through-hole includes a first through-hole provided on each of both sides of the first hollow portion in a longitudinal direction of the first hollow portion.

8. The acoustic wave device according to claim 7, wherein the at least one first through-hole further includes another first through-hole provided on one of the both sides of the first hollow portion in the longitudinal direction.

9. The acoustic wave device according to claim 1, wherein the at least one second through-hole includes a second through-hole provided on one side of the second hollow portion in a longitudinal direction of the second hollow portion.

10. The acoustic wave device according to claim 1, wherein the at least one second through-hole includes one second through-hole that communicates with each of two second hollow portions via a connection passage, each of the two second hollow portions including the second hollow portion.

11. The acoustic wave device according to claim 1, wherein the first functional electrode and the second functional electrode are each an IDT electrode including a pair of opposing busbars including a first busbar and a second busbar, one or more first electrode fingers extending from the first busbar, and one or more second electrode fingers extending from the second busbar.

12. The acoustic wave device according to claim 11, wherein a first region of the first resonator above the first hollow portion is larger than a second region of the second resonator above the second hollow portion, the first region being a region in which the first electrode fingers and the second electrode fingers are alternately arranged so as to respectively extend from the first busbar and the second busbar in the pair, the second region being a region in which third electrode fingers and fourth electrode fingers are alternately arranged so as to respectively extend from a third busbar and a fourth busbar in a pair.

13. The acoustic wave device according to claim 12, wherein the at least one first through-hole further includes another first through-hole provided in the first region.

14. The acoustic wave device according to claim 11, wherein d/p≤about 0.5 is satisfied, where d is a thickness of the piezoelectric layer, and p is a center-to-center distance between a first electrode finger and a second electrode finger that are adjacent to each other among the first electrode fingers and the second electrode fingers.

15. The acoustic wave device according to claim 14, wherein d/p is less than or equal to about 0.24.

16. The acoustic wave device according to claim 12, wherein
a region where a first electrode finger and a second electrode finger that are adjacent to each other among the first electrode fingers and the second electrode fingers overlap each other when viewed in a direction in which the first electrode fingers and the second electrode fingers are arranged is an excitation region; and
MR≤about 1.75 (d/p)+0.075 is satisfied, where MR is a metallization ratio that is a ratio of an area of the first electrode finger and the second electrode finger in the excitation region.

17. The acoustic wave device according to claim 1, wherein the acoustic wave device is structured to generate a bulk wave in a thickness-shear mode.

18. The acoustic wave device according to claim 1, wherein each of the first functional electrode and the second functional electrode includes an upper electrode in an upper portion of the piezoelectric layer and a lower electrode in a lower portion of the piezoelectric layer.

19. The acoustic wave device according to claim 1, wherein the piezoelectric layer includes lithium niobate or lithium tantalate.

20. The acoustic wave device according to claim 19, wherein
the lithium niobate or the lithium tantalate has Euler angles (φ, θ, ψ) within a range represented by Expression (1), Expression (2), or Expression (3):
(0°±10°,0° to 20°,any ψ) Expression (1)
(0°±10°,20° to 80°,0° to 60° (1−(θ−50)²/900)_{1/2}) or (0°±10°,20° to 80°,[180°−60° (1−(θ−50)²/900)^{1/2}] to 180°) Expression (2)
(0°±10°,[180°−30° (1−(ψ−90)²/8100)^{1/2}] to 180°,any ψ) Expression (3).

21. The acoustic wave device according to claim 1, wherein the first portion of the piezoelectric layer and the second portion of the piezoelectric layer are portions of a same piezoelectric layer.
